(19) United States
(12) Patent Application Publication
(10) Pub. No.: US 2025/0372346 A1
(43) Pub. Date: Dec. 4, 2025

(54) MARK POSITION MEASUREMENT METHOD, MULTI-CHARGED PARTICLE BEAM WRITING METHOD AND MULTI-CHARGED PARTICLE BEAM WRITING APPARATUS

(71) Applicant: NuFlare Technology, Inc., Yokohama-shi (JP)

(72) Inventors: Tsubasa NANAO, Yokohama-shi (JP); Hiroshi SATO, Yokohama-shi (JP); Kaoru TSURUTA, Yokohama-shi (JP)

(73) Assignee: NuFlare Technology, Inc., Yokohama-shi (JP)

(21) Appl. No.: 19/218,916

(22) Filed: May 27, 2025

(30) Foreign Application Priority Data
Jun. 3, 2024 (JP) 2024-090116

(51) Int. Cl. H01J 37/304; H01J 37/317

(52) U.S. Cl. CPC H01J 37/3045; H01J 37/3174; H01J 2237/30472

(57) ABSTRACT

In one embodiment, a mark position measurement method includes forming a multi-beam in which charged particle beams are arranged at a predetermined pitch, scanning a mark in a pseudo manner by sequentially switching an on-beam area in which beams in a partial area of the multi-beam are set ON and shifting an irradiation position of the charged particle beams, and detecting a reflected charged particle signal from the mark, the mark being provided at a predetermined position, and having a width greater than the predetermined pitch, and measuring a position of the mark based on the reflected charged particle signal detected. An average per unit time of a beam current in a substrate where the mark is formed is made constant at a time of switching of the on-beam area.

### CROSS REFERENCE TO RELATED APPLICATION

This application is based upon and claims benefit of priority from the Japanese Patent Application No. 2024-90116, filed on Jun. 3, 2024, the entire contents of which are incorporated herein by reference.

### FIELD

The present invention relates to a mark position measurement method, a multi-charged particle beam writing method and a multi-charged particle beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. The high-precision original pattern is written by using an electron-beam writing apparatus, in which a so-called electron-beam lithography technique is employed.

A writing apparatus that uses a multi-beam can emit more beams at one time than a writing apparatus that performs writing by a single electron beam, thus the throughput can be significantly improved. As a form of multi-beam writing apparatus, a multi-beam writing apparatus using a blanking aperture array substrate forms a multi-beam (a plurality of electron beams) by passing an electron beam emitted from an electron source through a shaping aperture array substrate having a plurality of openings. The multi-beam passes through corresponding blankers (electrode pairs) of the blanking aperture array substrate. The blanker has an electrode pair for individually deflecting beams, and includes an opening for beam passage between the electrode pair. One electrode of the blanker is fixed at ground potential, and the other electrode is switched between ground potential and another potential, thereby performing blanking deflection of the passing electron beam. A beam deflected by a blanker is blocked, and a beam not deflected is irradiated onto a substrate as an on-beam.

In multi-beam writing, a writing operation is temporarily suspended for a certain writing unit, a multi-beam is emitted (scanned) to a mark on the stage while being shifted, a reflected electronic signal from the mark is detected, the mark position is calculated from a result of the detection to determine the amount (the amount of shift of the entire beam) of beam drift, and drift correction is performed.

A phase shift method is known as a technique to improve the resolution in photolithography. A phase shift mask requires patterns in two layers: a light-shielding pattern layer and a half-tone pattern layer, thus position adjustment (alignment) accuracy when these patterns are overlaid is important. For example, a cross-mark pattern for alignment is created when the first layer pattern is formed. The cross-mark is scanned by a multi-beam to detect a reflected electronic signal, the cross-mark position is calculated from a result of the detection, and the writing position of the second layer pattern is adjusted.

In this manner, in the multi-beam writing, a mark provided on a stage or a substrate is scanned by a multi-beam to measure the position of the mark. Because the current density of a single beam is low, when the position of the mark is measured by a multi-beam, multiple beams in a specific area are set ON, and the mark is scanned by collectively treating these beams as a single beam. In this process, as illustrated in FIG. 15, a wide range greater than the sum of the size of a beam area BG1 and the width W of a mark M needs to be scanned. Thus, when a deflector deflects the multi-beam for scan, deflection distortion may occur or the beam may approach the deflector to cause a drift, making it difficult to measure the mark position accurately.

Japanese Unexamined Patent Application Publication No. 2021-132149 discloses a technique for measuring the mark position by scanning the mark while shifting the beam irradiation position by sequentially switching an on-beam area in which the beams in a partial area of the multi-beam are set ON. With this technique, the multi-beam does not need to be deflected, thus occurrence of deflection distortion can be prevented.

However, when a distribution of current amount is present in the beam array surface of the multi-beam, in other words, when the current density varies for each beam, it is difficult to measure the mark position accurately. For example, when an area other than the mark is irradiated with a beam with a high current density, and the mark is irradiated with a beam with a low current density, it is difficult to identify a signal peak caused by the mark from a result of detection of a reflected electronic signal, making it difficult to measure the mark position.

### BRIEF DESCRIPTION OF THE DRAWINGS

FIG. 1 is a schematic view of a multi-charged particle beam writing apparatus according to an embodiment of the present invention.

FIG. 2 is a plan view of a shaping aperture array substrate.

FIGS. 3A to 3D are views for explaining switch scan.

FIGS. 4A to 4C are views for explaining switch scan.

FIG. 5 is a graph illustrating an example of a result of detection of a reflected electronic signal.

FIG. 6 is a graph illustrating an example of a result of detection of a reflected electronic signal.

FIG. 7 is a view illustrating on-beam areas used for switch scan.

FIG. 8 is a graph illustrating an example of a result of detection of the beam current in each on-beam area used for switch scan.

FIG. 9 is a flowchart for explaining a writing method according to the embodiment.

FIGS. 10A to 10F are views illustrating the beams to be ON when switch scan is performed.

FIG. 11 is a graph illustrating an example of a result of detection of a reflected electronic signal.

FIG. 12 is a graph illustrating an example of a result of detection of a reflected electronic signal.

FIG. 13 is a graph illustrating an example of a result of detection of a reflected electronic signal.

FIG. 14 is a flowchart for explaining a writing method according to another embodiment.

FIG. 15 is a view for explaining deflection scan.

FIG. 16 is a schematic configuration view of an inspection apparatus.

### DETAILED DESCRIPTION

In one embodiment, a mark position measurement method includes forming a multi-beam in which charged particle beams are arranged at a predetermined pitch, scanning a mark in a pseudo manner by sequentially switching an on-beam area in which beams in a partial area of the multi-beam are set ON and shifting an irradiation position of the charged particle beams, and detecting a reflected charged particle signal from the mark, the mark being provided at a predetermined position, and having a width greater than the predetermined pitch, and measuring a position of the mark based on the reflected charged particle signal detected. An average per unit time of a beam current in a substrate where the mark is formed is made constant at a time of switching of the on-beam area.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

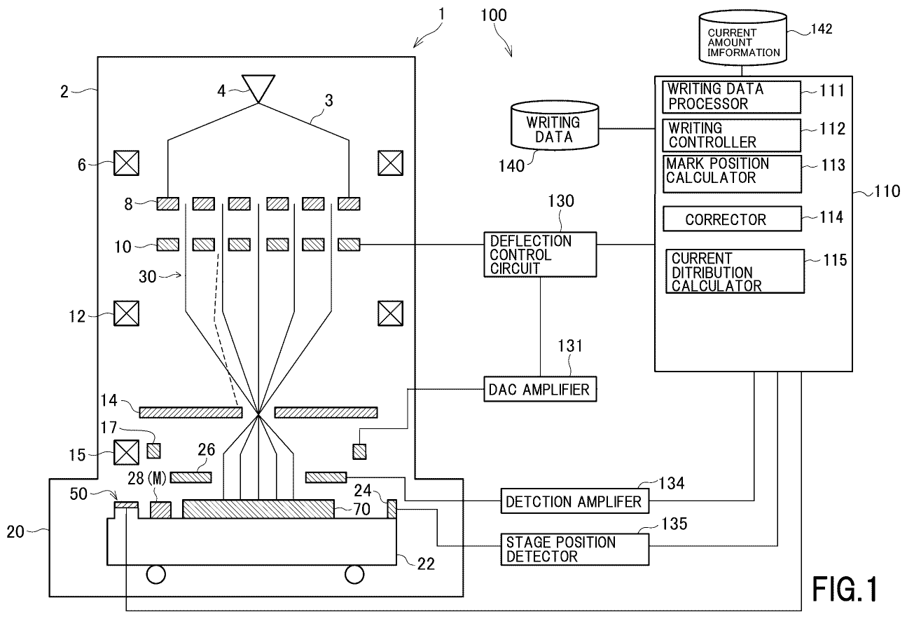

FIG. 1 is a conceptual view of a writing apparatus in the embodiment. In FIG. 1, the writing apparatus includes a writer 1 and a controller 100. The writing apparatus is an example of a multi-charged particle beam writing apparatus. The writer 1 includes an electron optical column 2 and a writing chamber 20. In the electron optical column 2, an electron source 4, an illumination lens 6, a shaping aperture array substrate 8, a blanking aperture array substrate 10, a reduction lens 12, a limiting aperture member 14, an objective lens 15, a deflector 17 and the like are disposed.

In the writing chamber 20, an XY stage 22 and a detector 26 are disposed. On the XY stage 22, a substrate 70 as an irradiation target (writing target) is disposed. The height of the substrate 70 is adjustable by a Z stage (not illustrated). The substrate 70 is e.g., mask blanks or a semiconductor substrate (silicon wafer).

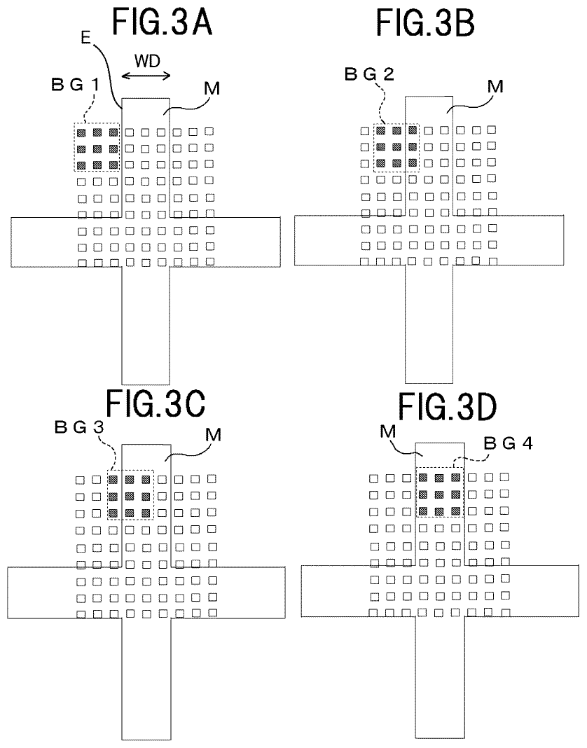

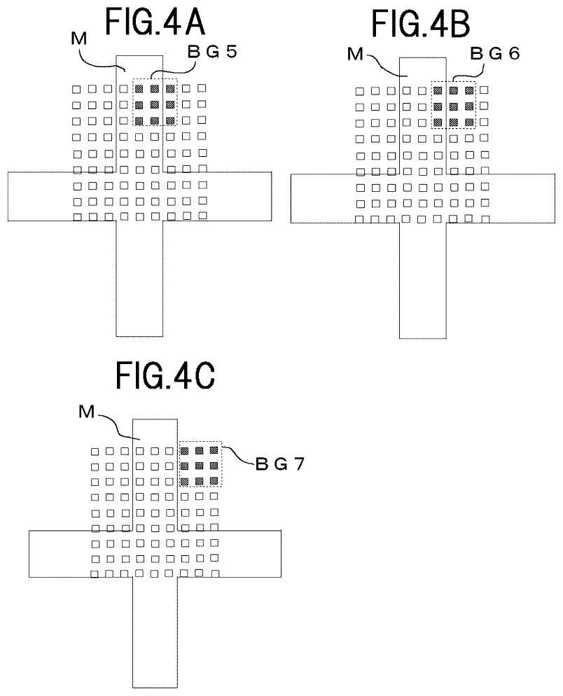

On the XY stage 22, a mirror 24 for measurement of the position of the XY stage 22 is disposed. In addition, on the XY stage 22, a mark substrate 28 is provided, in which the mark M (see FIGS. 3A to 3D, FIGS. 4A to 4C) for beam calibration is formed. The mark M is made of metal, and has e.g., a cross shape so that its position is easily detected by scanning an electron beam. The detector 26 detects a reflected electronic signal from the mark M when the cross of the mark M is scanned by an electron beam.

The XY stage 22 is provided with a current detector 50 at a position different from the position where the substrate 70 is placed. As the current detector 50, e.g., a Faraday cup may be used. The result of detection of the current detector 50 is transmitted to a control computer 110.

The controller 100 includes the control computer 110, a deflection control circuit 130, a digital/analog conversion (DAC) amplifier 131, a detection amplifier 134, a stage position detector 135, and storage devices 140 and 142. The storage devices 140, 142 are magnetic disk devices or the like. The storage device 140 receives writing data from the outside, and stores it. The storage device 142 stores the later-described current amount information.

The DAC amplifier 131 is coupled to the deflection control circuit 130. The DAC amplifier 131 is coupled to the deflector 17.

The control computer 110 includes a writing data processor 111, a writing controller 112, a mark position calculator 113, a corrector 114, and a current distribution calculator 115. The function of each component of the control computer 110 may be implemented by hardware or implemented by software. When the function is implemented by software, a program that implements at least part of the function of the control computer 110 may be stored in a recording medium, and read by a computer including a CPU or the like to cause the computer execute the program. The recording medium is not limited to a detachable medium such a magnetic disk or an optical disk, and may be a fixed recording medium such as a hard disk drive or a memory.

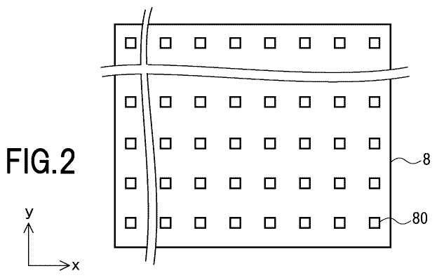

FIG. 2 is a conceptual view illustrating the configuration of the shaping aperture array substrate 8. As illustrated in FIG. 2, in the shaping aperture array substrate 8, openings 80 in m vertical (y direction) rows x n horizontal (x direction) rows (m, n≥2) are formed in a matrix form with a predetermined arrangement pitch.

An electron beam 3 emitted from the electron source 4 illuminates the shaping aperture array substrate 8 substantially perpendicularly via the illumination lens 6. The electron beam 3 illuminates an area including the openings 80 of the shaping aperture array substrate 8. Part of the electron beam 3 passes through a corresponding one of these multiple openings 80, thus, as illustrated in FIG. 1, a multi-beam 30 with predetermined pitch, size is formed. Note that a multi-beam may be formed using a photocathode.

In the blanking aperture array substrate 10, passage holes (openings), through each of which a beam (an individual beam) of the multi-beam 30 passes through, are formed at the positions corresponding to the openings 80 of the shaping aperture array substrate 8 illustrated in FIG. 2. In the vicinity of each passage hole, an electrode (a blanker i.e., a blanking deflector) for blanking deflection to deflect an individual beam is disposed.

The individual beams passing through the passage holes are each independently deflected by a voltage applied from a blanker. Blanking control is performed by this deflection. In this manner, multiple blankers perform blanking deflection on corresponding individual beams in the multi-beam which has passed through the multiple openings 80 of the shaping aperture array substrate 8.

The multi-beam 30 passing through the blanking aperture array substrate 10 is reduced in beam size and arrangement pitch by the reduction lens 12, and travels to the opening formed in the center of the limiting aperture member 14. An individual beam deflected by a blanker of the blanking aperture array substrate 10 deviates from its trajectory, and is displaced from the opening in the center of the limiting aperture member 14, and blocked by the limiting aperture member 14. In contrast, an individual beam not deflected by a blanker of the blanking aperture array substrate 10 passes through the opening in the center of the limiting aperture member 14.

The multi-beam 30 passing through the limiting aperture member 14 is adjusted in focus by the objective lens 15, and becomes a pattern image with a desired reduction ratio on the substrate 70. An electrostatic lens may be used as the objective lens 15. The deflector 17 collectively deflects the entire multi-beam passing through the limiting aperture member 14 in the same direction, and radiates the multi-beam to a writing position (irradiation position) on the substrate 70.

When the XY stage 22 is continuously moved, tracking-control is performed by the deflector 17 so that the writing position (irradiation position) of the beam follows the movement of the XY stage 22. The position of the XY stage 22 is measured using reflected light of a laser which is emitted from the stage position detector 135 to the mirror 24 on the XY stage 22.

The multi-beam emitted at one time is ideally arranged with a pitch which is the product of the arrangement pitch of the multiple openings 80 of the shaping aperture array substrate 8 and the above-mentioned desired reduction ratio. Note that such a pitch of the multi-beam is not necessarily required to be constant. The writing apparatus performs a writing operation using a raster scan method, by which a shot beam is successively emitted continuously, and when a desired pattern is written, beams needed according to the pattern are controlled to be beam-ON by the blanking control.

The writing data processor 111 of the control computer 110 reads writing data from the storage device 140, and performs data conversion in multiple stages to generate shot data. In the shot data, the presence and absence of irradiation to each of irradiation areas, the irradiation time and the like are defined, the irradiation areas being obtained by dividing a writing surface of the substrate 70 into multiple irradiation areas in a lattice pattern by the beam size, for example.

The writing controller 112 outputs a control signal to the deflection control circuit 130 based on the shot data and the stage position information. The deflection control circuit 130 controls the voltage applied to each blanker of the blanking aperture array substrate 10, based on the control signal. In addition, the deflection control circuit 130 calculates deflection amount data so that the beam is emitted to a desired position on the substrate 70, and outputs the deflection amount data to the DAC amplifier 131. The DAC amplifier 131 converts a digital signal into an analog signal, amplifies the signal, and applies the signal to the deflector 17 as a deflection voltage. The deflector 17 deflects the multi-beam according to the deflection voltage applied.

In the writing apparatus, beam drift may occur due to the effect of adhesion or the like of contamination, and deviation in the beam irradiation position may occur. Thus, it is necessary to temporarily suspend the pattern writing process at a predetermined timing, measure the mark position by scanning the mark M with a multi-beam, and make adjustment (drift correction) of the irradiation position.

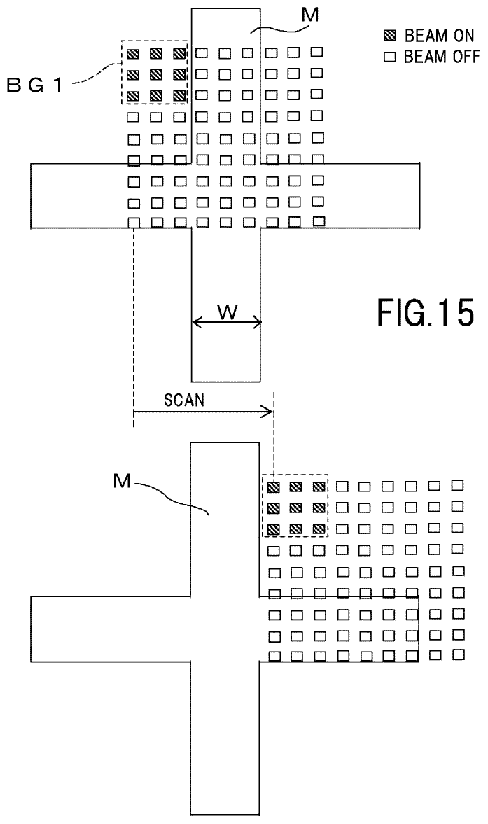

In the embodiment, the mark M is scanned in a pseudo manner by switching (shifting) the area to be beam-ON instead of deflecting the multi-beam and scanning the mark M as illustrated in FIG. 15. Hereinafter, deflecting the multi-beam (on-beam) by the deflector 17 and scanning the mark M is referred to as “deflection scan”, and scanning the mark M in a pseudo manner by switching the area to be beam-ON is referred to as “switch scan”.

An example of switch scan is illustrated in FIGS. 3A to 3D and FIGS. 4A to 4C. First, as illustrated in FIG. 3A, the beams in a partial area BG1 of the multi-beam are set ON, and the beams in other areas are set OFF. In this example, 9 (=3×3) beams in the area BG1 located at the upper left of 81 (=9×9) beams in FIG. 3A are set ON. The detector 26 detects a reflected electronic signal from the mark M. The width of the mark M is smaller than the size of the entire multi-beam, and greater than the pitch of the multi-beam on the substrate. Each on-beam area includes multiple individual beams which are arranged in a direction perpendicular to a mark edge E in a width direction WD of the mark M and in a direction (mark edge extension direction) parallel to the mark edge E in the width direction WD.

Next, as illustrated in FIG. 3B, the area to be beam-ON is shifted to the right by one row, and the beams in an area BG2 are set ON. The detector 26 detects a reflected electronic signal from the mark M.

Subsequently, as illustrated in FIG. 3C, FIG. 3D, FIG. 4A, FIG. 4B, FIG. 4C, the area to be beam-ON is shifted to the right by one row, and the beams in areas BG3, BG4, BG5, BG6, BG7 are successively set ON. Every time the area to be beam-ON is switched, the detector 26 detects a reflected electronic signal from the mark M.

As illustrated in FIG. 15, mark scan similar to the deflection scan of the mark M with the beams in the area BG1 is possible by successively switching the on-beam area from the area BG1 to the area BG7.

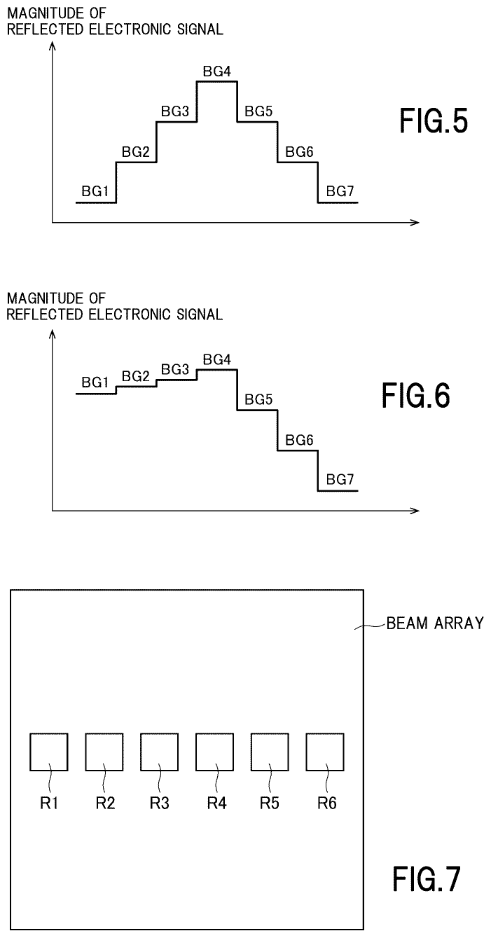

The result of detection of a reflected electronic signal by the detector 26 is ideally as illustrated in FIG. 5. The amount of reflected electrons from the mark M portion is greater than the amount of reflected electrons from the portion other than the mark M. The mark position calculator 113 detects a peak of the amount of reflected electrons from the result of detection of a reflected electronic signal by the detector 26, and calculates the mark position.

However, when a distribution of current amount is present in the beam array surface, it is difficult to identify the peak caused by the mark in the amount of reflected electrons. For example, when the beams in the area BG1 have a beam current higher than that of the beams in other areas, the result of detection of a reflected electronic signal from the switch scan of the mark M is as illustrated in FIG. 6, thus it is difficult to identify the peak caused by the mark.

Thus, in the embodiment, the beam current of an individual beam or a beam group obtained by grouping multiple individual beams is detected in the beam array surface, the beams outside the areas are also set ON so that the average per unit time of the beam current in the mark substrate is constant between the on-beam areas used for switch scan, and the number of beams to be ON is changed at the time of switching the on-beam area.

For example, the beam current of each of on-beam areas R1 to R6 used for switch scan as illustrated in FIG. 7 is detected using the current detector 50. In addition, the beam current of an individual beam or a beam group at a position other than the areas R1 to R6 in the beam array surface is detected using the current detector 50. The current distribution calculator 116 calculates a current distribution in the beam array surface from the result of detection of the current detector 50, and stores the current distribution in the storage device 142 as current amount information.

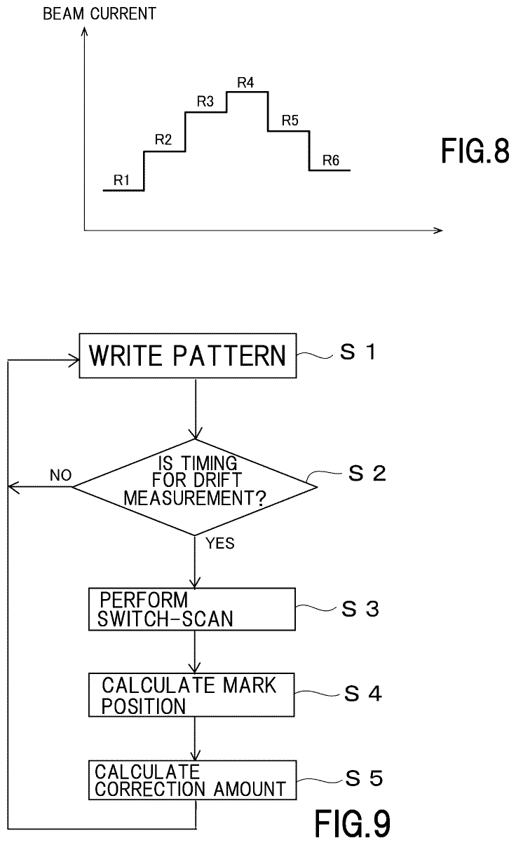

An example of beam currents in the areas R1 to R6 is illustrated in FIG. 8. To perform switch scan, the writing controller 112 refers to the current amount information, and adjusts the number of beams to be ON in the area other than the areas R1 to R6 used for switch scan, based on the difference in the beam current between the areas R1 to R6, and performs control so that the average per unit time of the current of the beam emitted to the mark substrate 28 is constant.

A writing method including drift correction using such switch scan will be described based on the flowchart illustrated in FIG. 9.

The substrate 70 is irradiated with a multi-beam to write a pattern (step S1). When a timing for drift measurement is reached after a lapse of a predetermined time (Yes in step S2), the pattern writing is temporarily suspended, and the mark M is switch-scanned (step S3).

As described above, beams outside the areas used for switch scan are set ON based on the difference in the beam current between the on-beam areas. An approximate position of the mark M is measured in advance, and a beam not hitting the mark M is set ON. It is preferable that the beams to be ON outside the areas R1 to R6 be not fixed, and selected at random.

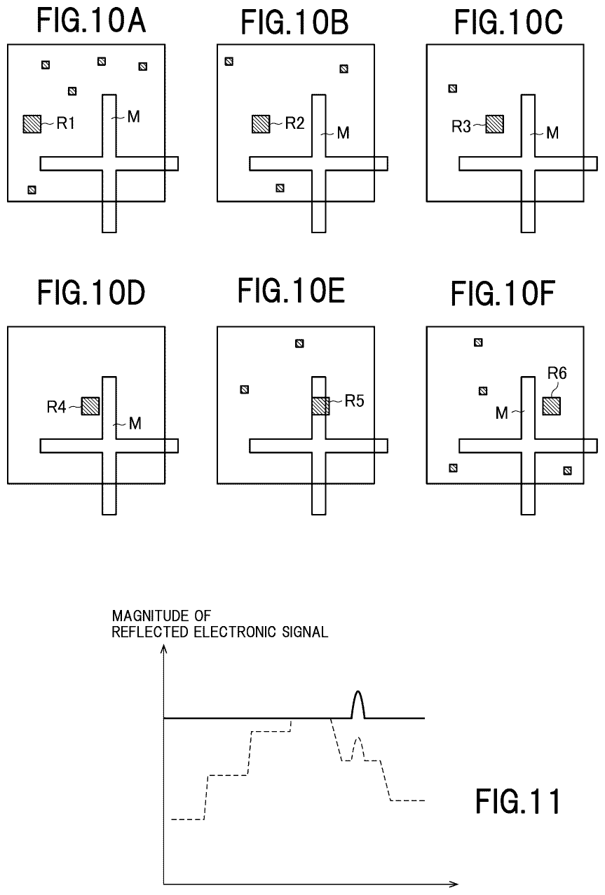

For example, as illustrated in FIG. 10A, when the area R1 is set ON, multiple beams are set ON at positions which are other than the on-beam area for switch scan (other than the area R1) and to which the mark M is not hit. In FIG. 10A, the beams to be ON are shaded with diagonal lines. Similarly, as illustrated in FIGS. 10B to 10F, when the areas R2 to R6 are set ON, one or multiple beams are set ON at positions which are other than the on-beam areas for switch scan and to which the mark M is not hit. An area with a smaller beam current in the areas R1 to R6 has a greater number of beams in other than the on-beam areas for switch scan. Note that when the beam in other than the on-beam areas is emitted at random, the beam may hit the mark M at random in a range having no effect on measurement.

As illustrated in FIG. 10D, in the area with the highest beam current (the area R4 in this example), the number of beams to be ON in other than the area may be 0.

Thus, to perform switch scan, the amount of current of the beam emitted to the mark substrate 28 can be made equal to that of the area (the area R4) with the highest beam current. Thus, the result of detection of a reflected electronic signal by the detector 26 is as illustrated in FIG. 11 (solid line). The reflected electronic signal is smoothed, and the gain and the offset can be adjusted so that the peak caused by the mark can be maximized, which facilitates the detection of the peak.

In contrast, when switch scan is performed without turning ON the beams outside the areas R1 to R6, the result of detection of a reflected electronic signal by the detector 26 is as illustrated in FIG. 11 (dashed line), thus it is difficult to identify the peak caused by the mark.

The mark position calculator 113 calculates the mark position from the result of detection of a reflected electronic signal by the detector 26 as illustrated in FIG. 11, and measures a deviation of the mark position based on the calculated mark position and the stage position information detected by the stage position detector 135 (step S4).

The corrector 114 calculates a correction amount (deflection correction amount) for correcting (calibrating) the deviation of the mark position by the deflector 17 (step S5). The calculated correction amount is stored in a storage device which is not illustrated. In the subsequent pattern writing (step S1), irradiation position adjustment such as drift correction can be made by deflecting the irradiation position (deflection position) of the multi-beam to a position displaced by the correction amount.

In this manner, according to the embodiment, the mark M is scanned in a pseudo manner by switching the on-beam area, thus occurrence of deflection distortion can be prevented. Since the beams outside the areas used for switch scan are set ON to achieve a constant average per unit time of the current of the beam emitted to the mark substrate 28, the peak caused by the mark can be easily detected from the result of detection of a reflected electronic signal, thus the mark position can be measured accurately. As a result, a position deviation due to beam drift can be corrected with high accuracy.

In the above embodiment, an example has been described in which the beams outside the areas R1 to R6 are set ON so that the current of beam emitted to the mark substrate 28 is made equal to that of the area (the area R4) with the highest beam current among the areas R1 to R6 used for switch scan; however, the current of beam emitted to the mark substrate 28 may be made equal to that of the area (the area R1) with the lowest beam current.

For example, the beam current of each of the areas R1 to R6 is detected using the current detector 50, and it is studied to what extent the number of beams to be ON in the area should be reduced so that the beam current is made equal to that of the area with the lowest beam current.

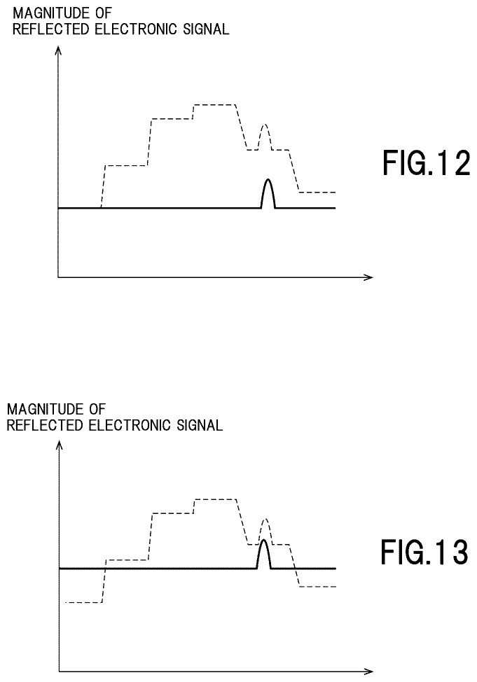

To perform switch scan, the amount of current of the beam emitted to the mark substrate 28 is made equal to that of the area with the lowest beam current, thus the result of detection of a reflected electronic signal by the detector 26 is as illustrated in FIG. 12 (solid line), and the peak caused by the mark can be easily detected. The dashed line in FIG. 12 shows the result of detection of a reflected electronic signal when control to make the amount of current of the beam emitted to the mark substrate 28 constant is not performed.

The process of turning ON the beams outside the areas so that the amount of current of the beam emitted to the mark substrate 28 is made equal to any value, and the process of reducing the number of beams to be ON in the areas may be combined.

In the areas (for example, the areas R1, R6) with a low beam current, the beams outside the areas are set ON. In the areas (for example, the areas R2 to R5) with a high beam current, the number of beams to be ON in the areas is reduced.

Thus, to perform switch scan, the amount of current of the beam emitted to the mark substrate 28 is made constant, thereby the result of detection of a reflected electronic signal by the detector 26 is as illustrated in FIG. 13 (solid line), and the peak caused by the mark can be easily detected. The dashed line in FIG. 13 shows the result of detection of a reflected electronic signal when control to make the amount of current of the beam emitted to the mark substrate 28 constant is not performed.

In the example illustrated in FIGS. 3A to 3D, FIGS. 4A to 4C, the example has been described in which the on-beam area is shifted by one row in the width direction (switch scan direction) of the mark M; however, the on-beam area may be shifted by multiple rows. However, for a less number “a” of rows by which the on-beam area is shifted, the mark position can be measured more accurately. For example, it is preferable that at least part of a first on-beam area and a second on-beam area shifted by “a” rows be overlapped.

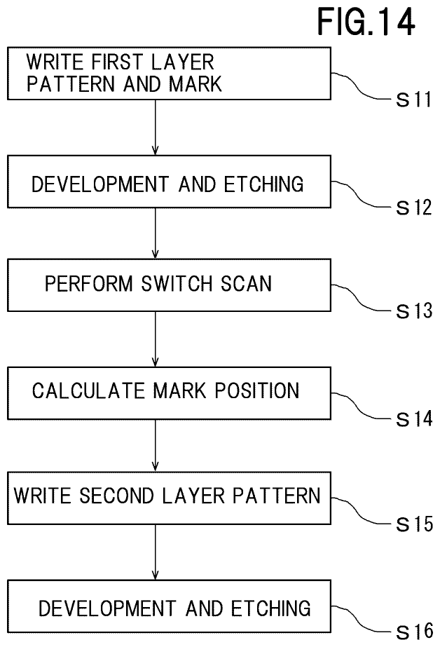

In the above embodiment, an example has been described in which the mark M on the XY stage 22 is switch-scanned; however, the mark for alignment provided in the substrate 70 at the time of formation of a phase shift mask may be switch-scanned. A pattern writing method for the phase shift mask will be described based on the flowchart illustrated in FIG. 14.

First, the substrate 70 is prepared in which a half-tone film, a light-shielding film, and a resist film are sequentially layered on a glass substrate. For example, an MoSi film may be used as the half-tone film. For example, a Cr film may be used as the light-shielding film. As a first layer writing step (step S11), a first layer main pattern is written in the center of the substrate 70 as an actual pattern. A cross-shaped mark pattern is then written in a mark area around the first layer main pattern.

Developing and etching processes are performed on the substrate 70 on which the first layer pattern and the mark pattern are written (step S12). The resist on the beam irradiation area is removed and a resist pattern is formed by the developing process. Using the resist pattern as a mask, exposed light-shielding film and half-tone film are removed by etching. Subsequently, the resist film is removed by ashing or the like, thereby forming the first layer main pattern and the mark around the main pattern on the substrate 70.

Furthermore, the substrate 70 on which the resist film is formed is transported to the writing chamber 20. When the second layer pattern is written, the mark formed around the first layer main pattern is switch-scanned to calculate the mark position (steps S13, S14). As in the above embodiment, when switch scan is performed, the beams outside the areas are set ON or the number of beams to be ON in the areas is reduced so that the amount of current of the beam emitted to the substrate 70 is constant.

Alignment calculation is performed based on the calculated mark position, and the second layer main pattern is written at the aligned position on the substrate 70 (step S15). The developing and etching processes are performed on the substrate 70 on which the second layer pattern is written to form the second layer pattern (step S16). In this manner, the phase shift mask can be manufactured.

The position of the mark formed along with the first layer pattern can be measured with high accuracy by the switch scan, thus highly accurate alignment can be implemented. As a result, a mask loss due to misalignment can be reduced.

Note that such switch scan can be used not only for the above-described drift correction and phase shift mask alignment, but also for writing position adjustment to avoid a dirty defective portion of an EUV mask, and reduction of phase defect or the like of a pattern at the time of EUV exposure can be achieved.

In the above embodiment, the configuration has been described in which to perform switch scan, the beams outside the areas (for example, outside the areas R1 to R6) are set ON, or the number of beams to be ON in the areas (for example, in the areas R1 to R6) is reduced so that the average per unit time of the current of beam emitted to the substrate with the mark formed is constant before and after the switching of the on-beam area; however, the beam-on time may be controlled by turning ON/OFF the beam. For example, in an area where the beam current is high, the beam-on time is made shorter than in an area where the beam current is low. The shot cycle may be changed by repeating ON/OFF of the beam so that the average per unit time of the current of beam emitted to the substrate is constant.

In the embodiment, the configuration has been described in which the beam current of an individual beam or a beam group in the beam array surface is detected using the current detector 50 such as a Faraday cup, and the beams outside the areas are set ON or the number of beams to be ON in the areas is reduced based on the result of detection; however, the portion other than the mark of the mark substrate 28 is irradiated with a beam, reflected electrons are detected by the detector 26, and the beams to be ON outside the areas and the beams to be ON in the areas may be determined, or the beam-on time may be controlled so that the average per unit time of the amount of detected reflected electrons is constant.

In the above embodiment, an example of a multi-beam writing apparatus has been described, but the invention is also applicable to a multi-beam inspection apparatus. For example, the multi-beam inspection apparatus includes: a primary optical system that irradiates the substrate 70 as an inspection target on the XY stage 22 with the multi-beam 30 as a primary beam; and a secondary optical system that guides multi-secondary electrons released from the substrate to a detector. The primary optical system includes the illumination lens 6, the shaping aperture array substrate 8, the blanking aperture array substrate 10, the reduction lens 12, the objective lens 15, and the deflector 17 (see FIG. 1).

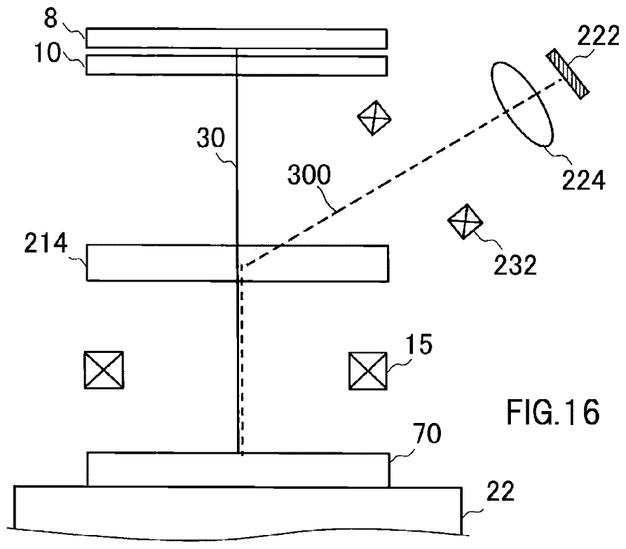

As illustrated in FIG. 16, the secondary optical system includes a beam separator 214, a projection lens 224, and an alignment coil 232. Triggered by irradiation of the substrate 70 with the multi-beam 30, a flux (multi-secondary electron 300) (the dotted line in FIG. 16) of secondary electrons including reflected electrons corresponding to the beams in the multi-beam 30 is released from the substrate 70. The beam separator 214 (for example, a Wien filter) generates an electric field and a magnetic field in orthogonal directions in a plane perpendicular to the direction (optical axis) in which the multi-beam 30 travels. The electric field exerts a force in the same direction regardless of the traveling direction of electrons. In contrast, the magnetic field exerts a force according to the Fleming's left-hand rule. Thus, the direction of a force exerted on electrons can be changed by the incident direction of electrons. The multi-beam 30 (primary electron beam) incident on the beam separator 214 from the upper side receives a force due to the electric field and a force due to the magnetic field that cancel each other, thus the multi-beam 30 goes straight downward. In contrast, the multi-secondary electron 300 incident on the beam separator 214 from the lower side receives a force due to the electric field and a force due to the magnetic field that are exerted in the same direction, thus the multi-secondary electron 300 is bent diagonally upward.

The multi-secondary electron 300 bent diagonally upward is projected onto a detector 222 while being refracted by the projection lens 224. The detector 222 collectively detects the projected multi-secondary electron 300. The detector 222 includes e.g., a diode sensor which is not illustrated.

In this manner, in the inspection apparatus, a primary electronic optical system that adjusts the trajectory of the multi-beam 30 (primary electron beam), and a secondary electronic optical system that adjusts the trajectory of the multi-secondary electron 300 (secondary electron) are disposed.

The mark M of the mark substrate 28 is scanned by the multi-beam to measure the mark position, and the primary electronic optical system is adjusted using the result of the measurement. In this process, as in the above embodiment, the mark M may be switch-scanned by sequentially switching the on-beam area, and along with this, the beams outside the areas may be set ON or the number of beams to be ON in the areas may be adjusted so that the average per unit time of the current of the beam emitted to the mark substrate 28 is constant.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A mark position measurement method comprising:
forming a multi-beam in which charged particle beams are arranged at a predetermined pitch;
scanning a mark in a pseudo manner by sequentially switching an on-beam area in which beams in a partial area of the multi-beam are set ON and shifting an irradiation position of the charged particle beams, and detecting a reflected charged particle signal from the mark, the mark being provided at a predetermined position, and having a width greater than the predetermined pitch; and
measuring a position of the mark based on the reflected charged particle signal detected,
wherein an average per unit time of a beam current in a substrate where the mark is formed is made constant at a time of switching of the on-beam area.

2. The mark position measurement method according to claim 1,
wherein the average per unit time of the beam current is made constant by changing a number of the beams to be ON.

3. The mark position measurement method according to claim 2,
wherein the number of the beams to be ON is adjusted in other than the on-beam area for scanning the mark in a pseudo manner.

4. The mark position measurement method according to claim 3,
wherein the beams to be ON in other than the on-beam area do not hit the mark.

5. The mark position measurement method according to claim 3,
wherein the beams to be ON in other than the on-beam area are selected at random for the on-beam area.

6. The mark position measurement method according to claim 3,
wherein the number of the beams to be ON in other than the on-beam area with a highest beam current is 0.

7. The mark position measurement method according to claim 2,
wherein the number of the beams to be ON is adjusted in the on-beam area for scanning the mark in a pseudo manner.

8. The mark position measurement method according to claim 1,
wherein part of the on-beam area after the switching overlaps with the on-beam area before the switching.

9. The mark position measurement method according to claim 1,
wherein the average per unit time of the beam current is made constant by changing a beam-on time for the on-beam area.

10. A multi-charged particle beam writing method,
wherein a pattern is written by adjusting an irradiation position of the multi-beam based on the position of the mark measured by the mark position measurement method according to claim 1.

11. A multi-charged particle beam writing apparatus comprising:
an aperture array substrate that forms a multi-beam in which charged particle beams are arranged at a predetermined pitch;
a stage on which a pattern writing target is placed;
a mark formed in a mark substrate or the pattern writing target on the stage, the mark having a width greater than the predetermined pitch;
a controller that scans the mark in a pseudo manner by sequentially switching an on-beam area in which beams in a partial area of the multi-beam are set ON, and shifting an irradiation position of the charged particle beams;
a detector that detects a reflected charged particle signal from the mark; and
a mark position calculator that calculates a position of the mark based on the reflected charged particle signal detected,
wherein the controller makes an average per unit time of a beam current constant in the mark substrate or the pattern writing target at a time of switching of the on-beam area.

12. The multi-charged particle beam writing apparatus according to claim 11,
wherein the controller makes the average per unit time of the beam current constant by changing a number of the beams to be ON.

13. The multi-charged particle beam writing apparatus according to claim 12,
wherein the controller adjusts the number of the beams to be ON in other than the on-beam area for scanning the mark in a pseudo manner.

14. The multi-charged particle beam writing apparatus according to claim 13,
wherein the beams to be ON in other than the on-beam area do not hit the mark.

15. The multi-charged particle beam writing apparatus according to claim 13,
wherein the controller randomly selects the beams to be ON in other than the on-beam area for the on-beam area.

16. The multi-charged particle beam writing apparatus according to claim 13,
wherein the controller sets the number of the beams to be ON in other than the on-beam area with a highest beam current to 0.

17. The multi-charged particle beam writing apparatus according to claim 12,
wherein the controller adjusts the number of the beams to be ON in the on-beam area for scanning the mark in a pseudo manner.

18. The multi-charged particle beam writing apparatus according to claim 11,
wherein the controller switches the on-beam area such that a part of the on-beam area after the switching overlaps with the on-beam area before the switching.

19. The multi-charged particle beam writing apparatus according to claim 11,
wherein the controller makes the average per unit time of the beam current constant by changing a beam-on time for the on-beam area.
